(19) United States
(12) Patent Application Publication
(10) Pub. No.: US 2006/0174835 A1
(43) Pub. Date: Aug. 10, 2006

(54) Vacuum processing apparatus and method of using the same

(76) Inventors: Misako Saito, Nirasaki-shi (JP); Teruyuki Hayashi, Nirasaki-shi (JP); Takayuki Komiya, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/346,301

(22) Filed: Feb. 3, 2006

(30) Foreign Application Priority Data
Feb. 10, 2005 (JP) 2005-033820
Feb. 10, 2005 (JP) 2005-033821

(51) Int. Cl. C23C 16/00

(52) U.S. Cl. 118/723 R; 118/719; 118/715

(57) ABSTRACT

A vacuum processing system includes a process chamber configured to accommodate a target object and perform a process thereon under a vacuum environment. The process chamber is provided with an exhaust system and a gas supply system. An ion generator configured to generate minus ions is disposed in a space outside the process chamber. The space is arranged to selectively communicate with the interior of the process chamber. A negative charge applicator is configured to form a negatively charged state of the target object within the process chamber.

### CROSS-REFERENCE TO RELATED APPLICATIONS

This application is based upon and claims the benefit of priority from prior Japanese Patent Applications No. 2005-033820, filed Feb. 10, 2005; and No. 2005-033821, filed Feb. 10, 2005, the entire contents of both of which are incorporated herein by reference.

### BACKGROUND OF THE INVENTION

1. Field of the Invention

The present invention relates to a vacuum processing apparatus and method of using the same, and particularly to a technique utilized in a semiconductor process. The term “semiconductor process” used herein includes various kinds of processes which are performed to manufacture a semiconductor device or a structure having wiring layers, electrodes, and the like to be connected to a semiconductor device, on a target object, such as a semiconductor wafer or a glass object used for an LCD (Liquid Crystal Display) or FPD (Flat Panel Display), by forming semiconductor layers, insulating layers, and conductive layers in predetermined patterns on the target object.

2. Description of the Related Art

In the process of manufacturing semiconductor devices, a semiconductor processing system of a multi-chamber type formed of a plurality of single-wafer type chambers is widely employed in order to process semiconductor wafers efficiently. In such a semiconductor processing system, the semiconductor wafer is transferred among the individual chambers under a vacuum environment shielded from the outside. As a result, it is possible to prevent to some extent the impurities, such as particles, from entering from the outside into the processing system.

It is possible, however, for the particles generated within the process chamber to drop onto a semiconductor wafer during the process of manufacturing the semiconductor devices. Various measures against this problem are proposed in, for example, Japanese Patent No. 3301408. This publication discloses an arrangement to provide a cover over the wafer and control the driving timing of the cover.

Also, in the multi-chamber type system, particles are generated from the driving mechanism of the transfer arm or the wafer cassette. Naturally, the particles thus generated may be attached to the semiconductor wafer. Further, the reaction by-products may be attached to the semiconductor wafer within the film-formation chamber.

Conventionally, a break filter is used to prevent the particles present inside the semiconductor processing system from rising under the vacuum condition or depositing onto the semiconductor wafer. However, use of the break filter is not effective for overcoming the problem of particle generation from inside the processing system, i.e., the particle generation from the driving mechanism of the transfer arm and from the wafer cassette.

Incidentally, it is possible to apply the so-called “plasma cleaning” for cleaning the interior of the process chamber. In this case, however, the process chamber cannot be used during the plasma cleaning operation. If the plasma cleaning is frequently applied, the operating rate of the entire semiconductor processing system is lowered.

It should also be noted that the semiconductor wafer that is processed within the semiconductor processing system is exposed to the atmosphere within the processing system (having atmospheric pressure) while the semiconductor wafer is being transferred from the wafer box or FOUP (Front Opening Unified Pod) to the process chamber. Therefore, it is necessary to keep clean the atmosphere within the processing system. A filter, such as an ULPA (Ultra Low Penetration Air) filter or a chemical filter, is used mainly for keeping clean the atmosphere within the processing system as disclosed in, for example, Jpn. Pat. Appln. KOKAI Publications No. 08-189681 and No. 09-275053.

An ULPA filter does function well in preventing the entry of the impurities from outside the system to some extent. However, it is impossible for the ULPA filter to remove the impurities generated inside the system. Also, the ULPA filter is incapable of removing the fine particles having a diameter not more than 0.1 μm. Also, it is absolutely necessary to use a chemical filter in order to remove ammonia and volatile organic substances. Further, it is necessary to apply maintenance frequently to the ULPA filter in view of the life of the filter itself, which lower the operating rate of the system.

### BRIEF SUMMARY OF THE INVENTION

An object of the present invention is to provide a vacuum processing system that can prevent particles from being attached to a target object to be processed and to provide a method of using the vacuum processing system.

According to a first aspect of the present invention, there is provided a vacuum processing system, comprising:

a process chamber configured to accommodate a target object and perform a process thereon under a vacuum environment;

an exhaust system configured to exhaust an interior of the process chamber;

a gas supply system configured to supply a process gas into the process chamber;

an ion generator configured to generate minus ions and disposed in a space outside the process chamber, the space being arranged to selectively communicate with the interior of the process chamber; and

a negative charge applicator configured to form a negatively charged state of the target object within the process chamber.

In a preferred mode of the system according to the first aspect, the system further comprises a control section configured to control an operation of the vacuum processing system, wherein the control section is arranged to form a negatively charged state of the target object by the negative charge applicator and to supply minus ions from the ion generator into the process chamber so as to charge negatively particles present therein, thereby preventing the particles from being attached to the target object. In this case, the control section may be arranged to supply minus ions into the process chamber after finishing the process within the process chamber and before transferring the target object out of the process chamber.

According to a second aspect of the present invention, there is provided a vacuum processing system, comprising:

a process chamber configured to accommodate a target object and perform a process thereon under a vacuum environment;

an exhaust system configured to exhaust an interior of the process chamber;

a gas supply system configured to supply a process gas into the process chamber;

a transfer chamber connected to the process chamber to transfer the target object into and out of the process chamber;

a load lock chamber capable of controlling inner pressure thereof between atmospheric pressure and a vacuum and connected to the transfer chamber;

an ion generator configured to generate minus ions that are supplied into the load lock chamber; and

an electric field-forming mechanism configured to form an electric field within the load lock chamber.

In a preferred mode of the system according to the second aspect, the system further comprises a control section configured to control an operation of the vacuum processing system, wherein the control section is arranged to form an electric field within the load lock chamber by the electric field-forming mechanism and to supply minus ions from the ion generator into the load lock chamber so as to charge negatively particles present therein, thereby collecting the particles by the electric field. In this case, the control section may be arranged to supply minus ions into the load lock chamber and form an electric field within the load lock chamber after adjusting pressure within the load lock chamber from atmospheric pressure to a vacuum, and, then, to continue to form the electric field within the load lock chamber until adjusting the pressure within the load lock chamber from a vacuum to atmospheric pressure.

According to a third aspect of the present invention, there is provided a method of using a vacuum processing system, comprising:

subjecting a target object to a process under a vacuum environment within a process chamber;

forming a negatively charged state of the target object within the process chamber; and

supplying minus ions into the process chamber to charge negatively particles present therein, thereby preventing the particles from being attached to the target object.

According to a fourth aspect of the present invention, there is provided a method of using a vacuum processing system, comprising:

forming an electric field within a hermetic chamber connected to a process chamber configured to accommodate a target object and perform a process thereon under a vacuum environment; and

supplying minus ions into the hermetic chamber to charge negatively particles present therein, thereby collecting the particles by the electric field.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view showing the layout of a semiconductor processing system according to a first embodiment of the present invention;

FIG. 2 exemplifies the structure of a minus ion generator included in the system shown in FIG. 1;

FIGS. 3A and 3B show the structure of a contact electrode included in the minus ion generator shown in FIG. 2 and a modification of the contact electrode;

FIG. 4 is a plan view showing the layout of the semiconductor processing system according to a second embodiment of the present invention;

FIG. 5 shows the structure of a processing apparatus that can be used for forming the process chamber included in the system shown in each of FIGS. 1 and 4;

FIG. 6 is a plan view showing the layout of a semiconductor processing system according to a third embodiment of the present invention; and

FIG. 7 shows the structure of a chamber apparatus that can be used for forming one of the load lock chamber and the storage chamber included in the system shown in each of FIGS. 1, 4 and 6.

### DETAILED DESCRIPTION OF THE INVENTION

Embodiments of the present invention will now be described with reference to the accompanying drawings. In the following description, the constituent elements having substantially the same function and arrangement are denoted by the same reference numerals, and a repetitive description will be made only when necessary.

### Semiconductor Processing System According to First Embodiment

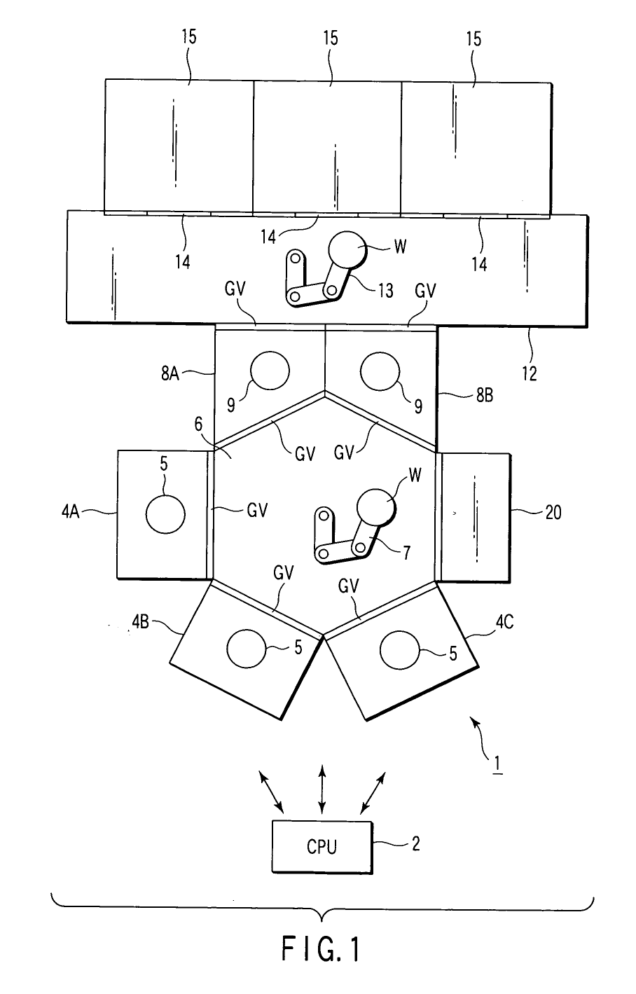

FIG. 1 is a plan view showing the layout of a semiconductor processing system according to a first embodiment of the present invention. As shown in the drawing, this semiconductor processing system 1 has a multi-chamber type structure including a plurality of single-object type process chambers. Each process chamber is arranged to accommodate a single semiconductor wafer W used as a target object to be processed, and perform a process thereon under a vacuum environment. The operation of the semiconductor processing system 1 is controlled by a CPU 2.

To be more specific, the processing system 1 according to this embodiment includes a hexagonal common transfer chamber 6. Connected to the common transfer chamber 6 are three process chambers 4A, 4B, and 4C and two load lock chambers 8A and 8B. Further, a minus ion generator 20 is disposed along the remaining one sidewall of the common transfer chamber 6. The minus ions generated in the minus ion generator 20 can be supplied into the process chambers 4A, 4B, and 4C, the transfer chamber 6, and the load lock chambers 8A and 8B through ion transfer tubes described later.

The pressure inside each of the process chambers 4A, 4B, and 4C can be controlled by gas supply and vacuum-exhaust into and from the chamber. A worktable 5 for supporting a semiconductor wafer W used as a target object is disposed in each of the process chambers 4A, 4B, and 4C. Various processes are applied to the semiconductor wafer W under the state that the semiconductor wafer W is disposed on the worktable 5. The process chambers 4A to 4C are connected to sidewalls of the hexagonal transfer chamber 6 with gate valves GV interposed between the process chambers and the transfer chamber 6.

The pressure inside the common transfer chamber 6 can also be controlled by gas supply and vacuum-exhaust into and from the transfer chamber 6. A transfer mechanism 7, which is retractable/extendible and rotatable to transfer the wafer W, is disposed within the transfer chamber 6. The transfer mechanism 7 is capable of transferring the wafer W into each of the process chambers 4A to 4C, and the load lock chambers 8A and 8B through the corresponding gate valve GV that is opened.

The load lock chambers 8A and 8B are connected to the transfer chamber 6 via the gate valves GV. The pressure inside the load lock chambers 8A and 8B can also be controlled between atmospheric pressure and a vacuum by gas supply and vacuum-exhaust into and from the load lock chambers 8A and 8B. A worktable 9 for temporarily supporting the semiconductor wafer W is disposed within each of the load lock chambers 8A and 8B.

The load lock chambers 8A and 8B are also connected to a loader module 12 via gate valves GV. The loader module 12 is provided with ports 14 each configured to place thereon a cassette for storing a plurality of wafers W. A transfer-arm mechanism 13, which is retractable/extendible and rotatable, is disposed within the loader module 12, and is configured to be movable along a guide rail (not shown).

The transfer-arm mechanism 13 is capable of taking a wafer W out of a wafer cassette 15 placed on the port 14 to transfer the wafer W into the load lock chamber 8A or 8B. The wafer W transferred into the load lock chamber 8A or 8B is further transferred by the transfer mechanism 7 disposed within the transfer chamber 6 into each of the process chambers 4A to 4C. The wafer processed in the process chambers 4A to 4C is transferred to the outside by the route opposite to the route of transferring the wafer W into the process chambers 4A to 4C described above.

The process chambers 4A to 4C are arranged to apply various processes, such as a film formation (CVD, PVD), oxidation, diffusion, annealing, and heating, to a semiconductor wafer W used as a target object. The types of the process chambers can be combined in various fashions depending on the kind of semiconductor devices to be manufactured. The semiconductor processing is carried out in general under the vacuum environment, though the processing may be carried out under atmospheric pressure in some cases depending on the mode of the processing.

The minus ions supplied from the minus ion generator 20 into the process chambers 4A to 4C, the transfer chamber 6, and the load lock chambers 8A and 8B are used for negatively charging particles present within each of these chambers. Where the target object or wafer W is negatively charged while the particles are negatively charged, the particles are prevented from being attached to the wafer W. Also, where an electric field is formed within the chamber while the particles are negatively charged, the electric field causes the particles to be collected on an electrode-function portion on the positive side.

In this embodiment, the minus ions are formed of, for example, oxide ions (O²⁻), oxygen minus ion radicals (O⁻) or a mixture of oxide ions and oxygen minus ion radicals (monatomic ion).

<Minus Ion Generator>

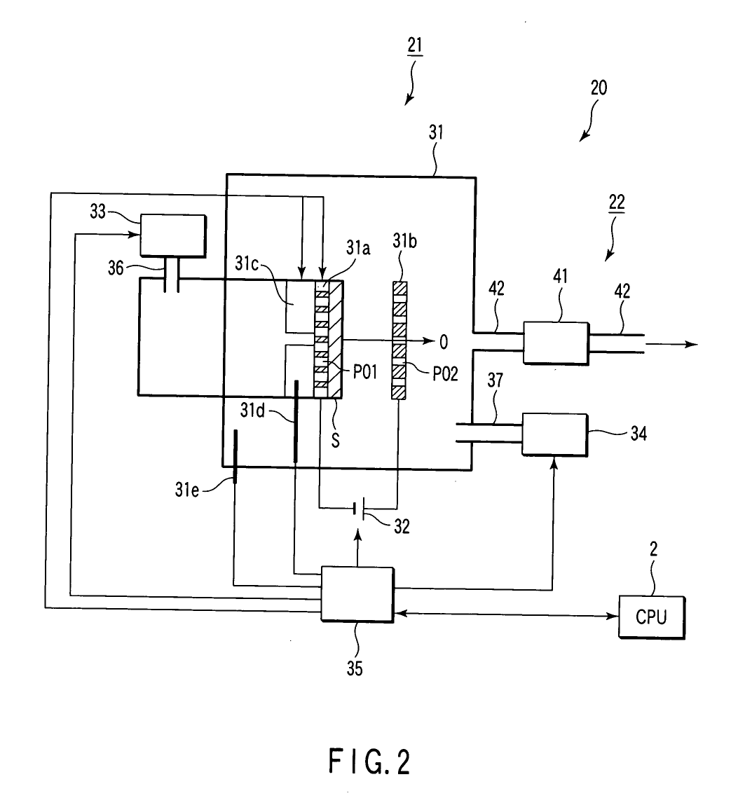

FIG. 2 exemplifies the specific structure of the minus ion generator 20. As shown in FIG. 2, the minus ion generator 20 comprises an ion extraction section 21 and an ion transfer section 22. Arranged in the ion extraction section 21 are a hermetic container 31, a contact electrode (negative electrode) 31a, an extraction electrode (positive electrode) 31b, a heater 31c, a temperature sensor 31d, a pressure sensor 31e, a DC power supply 32, a gas supply portion 33, an exhaust portion 34, a control portion 35, a gas supply line 36, and a gas exhaust line 37.

The hermetic container 31 defines a process space for forming the minus ions, i.e., oxide ions (O²⁻), oxygen minus ion radicals (O⁻) or a mixture of the oxide ions and the oxygen minus ion radicals (monatomic ion). Therefore, a source material containing minus ions, i.e., a minus ion source S, is contained in the hermetic container 31. The materials disclosed in, for example, “Hideo Hosono et al., Ceramics 37 (2002) No. 12, p 968-971 [Engineering of active oxygen in a nano porous crystal 12CaO.7Al₂O₃ and Application thereof]” and “K. Hayashi et al., Nature Vol. 419, p 462 (2002) [Light-induced conversion of an insulating refractory oxide into a persistent electronic conductor]” can be used as the minus ion source S.

The ion source S is disposed on one side of the contact electrode 31a, and the heater 31c is disposed on the other side of the contact electrode 31a. The temperature sensor 31d is arranged to measure the temperature of the heater 31c. The contact electrode 31a is provided with at least one aperture PO1 through which the source material gas supplied from the gas supply portion 33 flows. The source material gas is selectively supplied through the aperture PO1 onto that surface of the ion source S which is in contact with the contact electrode 31a. The extraction electrode 31b is disposed somewhat apart from the contact electrode 31a in a manner to face the contact electrode 31a with the ion source S interposed therebetween. The extraction electrode 31b is provided with an aperture PO2 through which the minus ions generated from the ion source S flow.

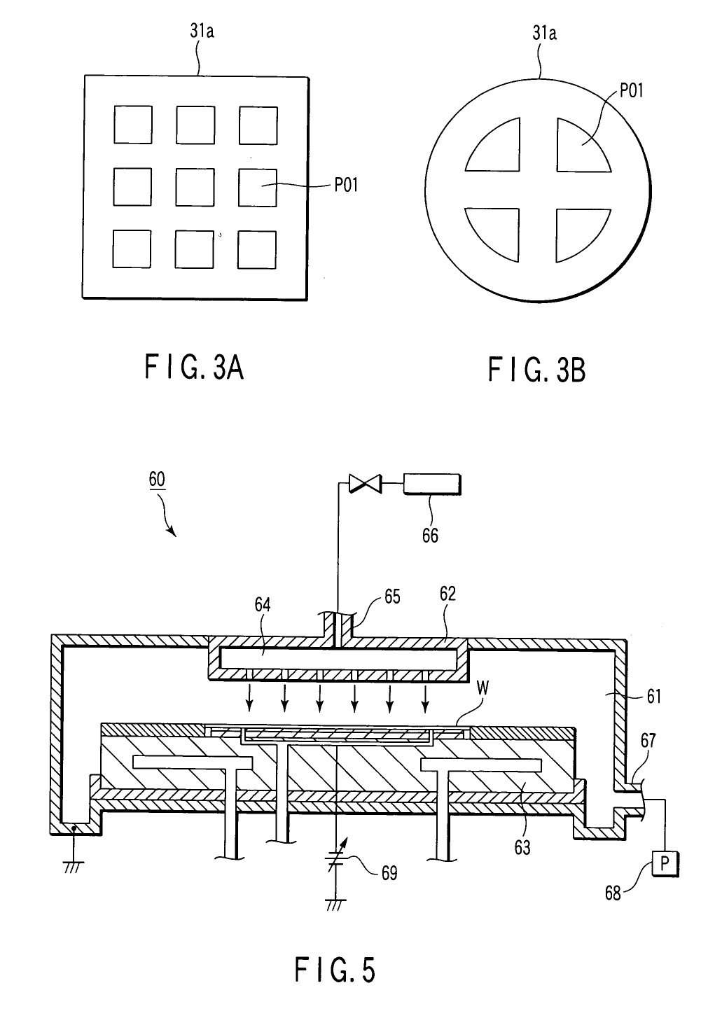

FIG. 3A shows the structure of the contact electrode 31a included in the minus ion generator 20 shown in FIG. 2, and FIG. 3B shows a modified structure of the contact electrode 31a. As shown in the drawings, the aperture PO1 can be shaped to conform to the outer shape of the contact electrode 31a.

The heater 31c is set to heat the ion source S to a temperature at which minus ions can be drawn out easily. In this embodiment, the temperature of the interior of the hermetic container 31 heated by the heater 31c is set at, for example, about 250 to 1,000° C., preferably at about 400 to 800° C., more preferably at about 700° C. If the temperature of the interior of the hermetic container 31 is set at a level not higher than 250° C., the minus ions within the ion source S are not activated and becomes difficult to draw out. On the other hand, if the temperature noted above is not lower than 1,000° C., active minus ions are generated in a very large amount, compared with the ordinary case, with the result that the ion source S may be denatured. Also, under such a high temperature, many restrictions are required. For example, it is necessary to use a special ceramic material or a metal in order to secure a high resistance to heat at the portion where the ion source S is mounted.

The pressure sensor 31e is arranged to measure the pressure inside the hermetic container 31. The pressure inside the hermetic container 31 is set such that the minus ions drawn out of the ion source S can be supplied smoothly into the ion transfer section 22. For example, the pressure inside the hermetic container 31 is set at about 10⁻³ Pa in this embodiment.

The DC power supply 32 is arranged to apply a predetermined voltage between the contact electrode 31a and the extraction electrode 31b in accordance with the control performed by the control portion 35. As a result, an electric field optimum for taking out the minus ions is applied to the ion source S set on the contact electrode 31a. When the ion source S is heated to a predetermined temperature by the heater 31c, the minus ions are drawn out of the ion source S by the electric field applied to the ion source S.

If the electric field applied to the ion source S is too weak, it is impossible to draw out the minus ions required for the processing. On the other hand, if an excessively strong electric field is applied to the ion source S, minus ions are drawn out in an amount larger than the amount required for processing particles within the chamber. It should also be noted that, if the minus ions are drawn out in an amount larger than required, reactions are brought about between the minus ions and the components of the minus ion generator 20 (such as the extraction electrode 31b, the heater 31c, and the inner wall of the hermetic container 31), so as to bring about an adverse effect.

Under the circumstances, the voltage of the DC power supply 32 is set such that the electric field applied to the ion source S has an intensity suitable for taking out the required amount of the minus ions. To be more specific, the voltage of the DC power supply 32 is set such that the electric field applied to the ion source S has an intensity of about 100 to 600 V/cm, preferably about 200 to 500 V/cm, and more preferably about 300 V/cm. If the intensity of the electric field is not lower than 600 V/cm, electrical discharge may be caused between the electrodes 31a and 31b. Also, if the intensity of the electric field is lower than 100 V/cm, minus ions may become difficult to drawn out.

The gas supply portion 33 is connected to the hermetic container 31 via the gas supply line 36. The gas supply portion 33 supplies a gas into the hermetic container 31 to replenish the ion source S, from which the minus ions have been drawn out, with the new minus ions. In this embodiment, oxygen gas is supplied at a partial pressure higher than the inner pressure of the hermetic container 31. In this case, a gradient of the oxygen partial pressure is formed between both sides of the ion source S to form a driving force of the ion stream flowing through the ion source S toward the extraction electrode. It follows that the minus ions can be drawn out continuously from the ion source S during the processing of the target object.

The exhaust portion 34 is connected to the hermetic container 31 via the exhaust line 37. The exhaust portion 34 comprises, for example, an exhaust pump to exhaust gas from the hermetic container 31 to the outside and to set the pressure within the hermetic container 20 at a predetermined level in accordance with the control performed by the control portion 35.

The control portion 35 is operated under the control of the CPU 2. A program for taking out the minus ions from the ion source S is stored in the control portion 35. The control portion 35 controls the operation of the ion extraction section 21 in accordance with the program stored in the control portion 35 to draw out minus ions from the ion source S.

The ion transfer section 22 comprises an ion distributing portion 41 and an ion transfer tube 42. The ion distributing portion 41 is connected to, for example, the process chambers 4A to 4C, the transfer chamber 6, and the load lock chambers 8A and 8B via the ion transfer tube 42. A carrier gas is supplied into the ion distributing portion 41 to cause the minus ions drawn out from the ion extraction section 21 to be supplied into the process chambers 4A to 4C, the transfer chamber 6, and the load lock chambers 8A and 8B. In this embodiment, an inactive gas or a mixed gas consisting of an inactive gas and a source material gas is supplied as the carrier gas into the ion distributing portion 41 at a flow rate of about 50 sccm in accordance with the pressure inside the hermetic container 31.

As described above, the minus ions can be obtained by a simple method of heating the ion source S and applying an electric field to the heated source S. As a result, the ion extraction section 21 can be of a simple structure as described above.

It is probable that undesired ions, such as H⁻ ions, are drawn out from the ion source S together with the desired ions, such as oxide ions (O²⁻). In this case, an ion selecting unit formed of, for example, a mass separator, may be arranged between the ion extraction section 21 and the ion transfer section 22 to perform the single-species selection, i.e., the selection of the oxide ions (O²⁻) or the oxygen minus ion radicals (O⁻).

The treatment using the minus ions can be performed under a pressure close to atmospheric pressure. Therefore, the minus ion generator can be mounted to or combined with another apparatus for executing a process under atmospheric pressure, without mounting a complex pressure control mechanism, etc.

For example, the minus ion generator can be mounted to or combined with a cleaning apparatus, a plating apparatus, or a wafer probing apparatus to use the minus ion generator before or after the cleaning treatment, the plating treatment, or the probing treatment that are carried out under atmospheric pressure. Incidentally, in the plating apparatus or the wafer probing apparatus, a metal is present on the surface of the semiconductor wafer and makes it difficult to remove the organic material by means of oxidation and, thus, the organic material is removed by means of reduction utilizing hydrogen.

In this embodiment, the minus ion generator 20 can be modified in various fashions as required. For example, the temperature and pressure within the hermetic container 31 are changed in accordance with the environment in which the minus ion generator 20 is used and in accordance with the kind of the minus ion source used.

### Semiconductor Processing System According to Second Embodiment

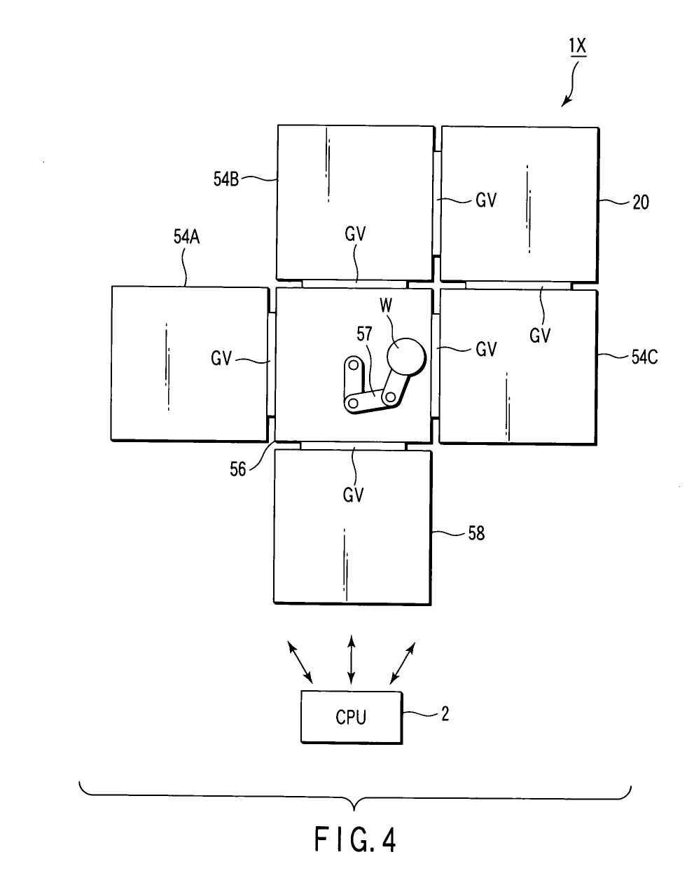

FIG. 4 is a plan view showing the layout of a semiconductor processing system according to a second embodiment of the present invention. This semiconductor processing system 1X also has a multi-chamber structure including a plurality of single-object type process chambers. Each process chamber is arranged to accommodate a single semiconductor wafer W used as a target object to be processed, and perform a process thereon under a vacuum environment. The operation of the semiconductor processing system 1X is controlled by a CPU 2.

To be more specific, in this embodiment, the processing system 1X comprises a rectangular common transfer chamber 56. Three process chambers 54A, 54B, and 54C and a single load lock chamber 58 are connected to the common transfer chamber 56. These chambers 54A to 54C and 58 are connected to the sidewalls of the transfer chamber 56 with gate valves GV interposed therebetween.

Each of the process chambers 54A, 54B, and 54C is arranged to accommodate a single semiconductor wafer W used as the target object, and perform a process thereon under a vacuum environment, like the process chambers 4A to 4C described previously. Also, the transfer chamber 56 and the load lock chamber 58 are capable of controlling the inner pressure by gas supply and vacuum-exhaust into and from the transfer chamber 56 and the load lock chamber 58 like the transfer chamber 6 and the load lock chambers 8A and 8B described previously. A transfer mechanism 57, which is retractable/extendible and rotatable to transfer the wafer W, is disposed within the transfer chamber 56. The transfer mechanism 57 is capable of transferring the wafer W into and out of each of the process chambers 54A to 54C, and the load lock chamber 58 through the corresponding gate valve GV that is opened.

A minus ion generator 20 is disposed in the space between the process chambers 54B and 54 C. The minus ion generator 20 is connected to the sidewalls of the process chambers 54B and 54C with gate valves GV interposed therebetween. Further, the minus ion generator 20 is connected as required to the process chamber 54A, the transfer chamber 56, and the load lock chamber 58 via the ion transfer tubes described previously.

Depending on the kind of the semiconductor devices to be manufactured, the number of process chambers disposed in the semiconductor processing system may be increased. In this case, it is necessary to take an appropriate measure in the arrangement of the minus ion generator 20. Also, the minus ion generator 20 may be directly connected to the film-formation process chamber in which particles are generated in a relatively large amount to facilitate the use of the minus ion generator 20. In this case, it is possible to lower the frequency of the plasma cleaning processes applied to the film-formation process chamber.

Incidentally, it is not absolutely necessary to arrange a single minus ion generator 20. A plurality of minus ion generators 20 may be disposed in accordance with the process environment. For example, in the semiconductor processing system for forming a film having a high degree of integration under an environment heavily contaminated with particles, it is possible to improve the working ratio and the yield of the entire system by arranging a plurality of the minus ion generators 20.

<Process Chamber>

FIG. 5 is a cross sectional view showing the structure of a process apparatus 60 that can be used as one of the process chambers 4A to 4C and 54A to 54C shown in FIGS. 1 and 4. The process apparatus 60 can take various structures in accordance with the object of the semiconductor processing system 1. Employed in the example shown in FIG. 5 is a parallel plate type plasma CVD apparatus. Specifically, in the process apparatus 60, a semiconductor wafer W is placed between a pair of electrodes, and the reaction gas is turned into plasma under the vacuum environment to carry out a predetermined film formation.

To be more specific, the process apparatus 60 comprises a process chamber 61, which is connected to an exhaust pump 68 formed of, for example, a turbo molecular pump via an exhaust line 67. An upper electrode 62 and a lower electrode 63 are disposed to face each other within the process chamber 61. The upper electrode 62 is formed as a shower head comprising a gas head 64 and a large number of gas delivery holes 64a. The gas head 64 is connected to a gas source 66 via a gas supply line 65. Various gases are supplied from the gas source 66 into the process chamber 61 in accordance with the process to be carried out, such as the film-formation process or cleaning process. On the other hand, the lower electrode 63 is used as a worktable for supporting the semiconductor wafer W. A bias power supply 69 for applying a negative bias voltage of, for example, about −5 to −50V to the semiconductor wafer W is connected to the lower electrode 63.

The worktable 63 and the inner wall of the process chamber 61 are heated by a heater (not shown) to a temperature suitable for removing the particles attached thereto. A high reactivity of the minus ions can be obtained by maintaining the appropriate temperature. To be more specific, the temperature of the worktable 63 and the inner wall of the process chamber 61 is set at 30 to 150° C., preferably 80 to 100° C.

### Operation of Minus Ion Generator in First or Second Embodiment

The operation of the minus ion generator 20 included in the semiconductor processing system 1 or 1X in the first or second embodiment of the present invention will now be described. For example, after the process within the process chamber 61 is finished, minus ions are supplied from the minus ion generator 20 into the process chamber 61 to charge negatively the particles. Where the negatively charged state of the semiconductor wafer W is formed in this stage, it is possible to prevent the particles from being attached to the semiconductor wafer W in transferring the wafer W out of the process chamber 61.

Accordingly, the CPU 2 for controlling the operation of the semiconductor processing system 1 or 1X first acts to place the semiconductor wafer W in the process chamber 61 and process the semiconductor wafer W under the vacuum environment. During or after the processing of the semiconductor wafer W, a negative bias voltage is applied from the bias power supply 69 to the wafer W to form the negatively charged state of the wafer W. Also, after the processing within the process chamber 61, the control portion 35 is controlled to supply minus ions into the process chamber 61, thereby negatively charging the particles within the process chamber 61. Then, the wafer W is transferred out of the process chamber 61, while preventing the particles from being attached to the wafer W.

Incidentally, the member for forming the negatively charged state of the semiconductor wafer W is not limited to a DC power supply. When it comes to, for example, a plasma etching process apparatus, if the lower electrode is supplied with an RF power having a frequency to which positive ions cannot follow, electrons are accumulated in the semiconductor wafer W and charge negatively the wafer W. Accordingly, the mechanism for forming a negatively charged state of the wafer W used as the target object is also called a negative charge applicator in the present specification.

The control portion 35 of the minus ion generator 20 performs the following control to generate minus ions. Incidentally, in the minus ion generator 20, the ion source S is fixed in advance to the contact electrode 31a as shown in FIG. 2. Also, the ion transfer tube 42 included in the ion transfer section 22 is connected in advance to a predetermined chamber. Further, in the following description, the process chamber 61 representing the process chambers 4A to 4C and 54A to 54C is regarded as the predetermined chamber. However, the predetermined chamber may represent any of the transfer chambers 6 and 56 and the load lock chambers 8A, 8A, and 58.

To be more specific, the gas supply portion 33 is controlled first to supply an oxygen gas (or a mixture of an oxygen gas and an inactive gas) into the hermetic chamber 31. Then, the exhaust portion 34 is controlled by using the result of the measurement by the pressure sensor 31e to set the inner pressure of the hermetic container 31 at a predetermined value (about 10⁻³ Pa).

Also, the heater 31c is controlled by using the result of the measurement by the temperature sensor 31d to heat the ion source S set on the contact electrode 31a to about 700° C. Then, the DC power supply 32 is controlled to apply a voltage between the contact electrode 31a and the extraction electrode 31b, thereby applying an electric field of a predetermined intensity to the ion source S. As a result, minus ions within the ion source S are drawn out by the applied electric field and supplied into the ion transfer section 22 through the aperture formed in the extraction electrode 31b.

The minus ions drawn out from the ion extraction section 21 are transferred by the ion distributor 41 included in the ion transfer section 22 into the process chamber 61 together with a carrier gas. At this time, the temperature and the pressure within the process chamber 61 are measured by the temperature sensor and the pressure sensor (not shown) to set the temperature and the pressure within the process chamber 61 at the values suitable for ionizing the particles under the control by the CPU 2.

The minus ions supplied by the ion distributor 41 into the process chamber 61 act on particles within the process chamber 61. To be more specific, the oxygen minus ions comprising monatomic ions selected from the group consisting of oxide ions, oxygen minus ion radicals, and mixture of oxide ions and oxygen minus ion radicals serve to charge negatively the particles. At this time, where the semiconductor wafer W is charged negative within the process chamber 61, it is possible to prevent the charged particles from being attached to the wafer W.

Incidentally, if an electric field is formed within a chamber to which minus ions are supplied, it is possible for the negatively charged particles to be collected by the function of the electric field, as described later. In the case of the process chamber 61, it is possible to utilize the upper electrode 62 and the lower electrode 63 for forming the electric field.

### Semiconductor Processing System According to Third Embodiment

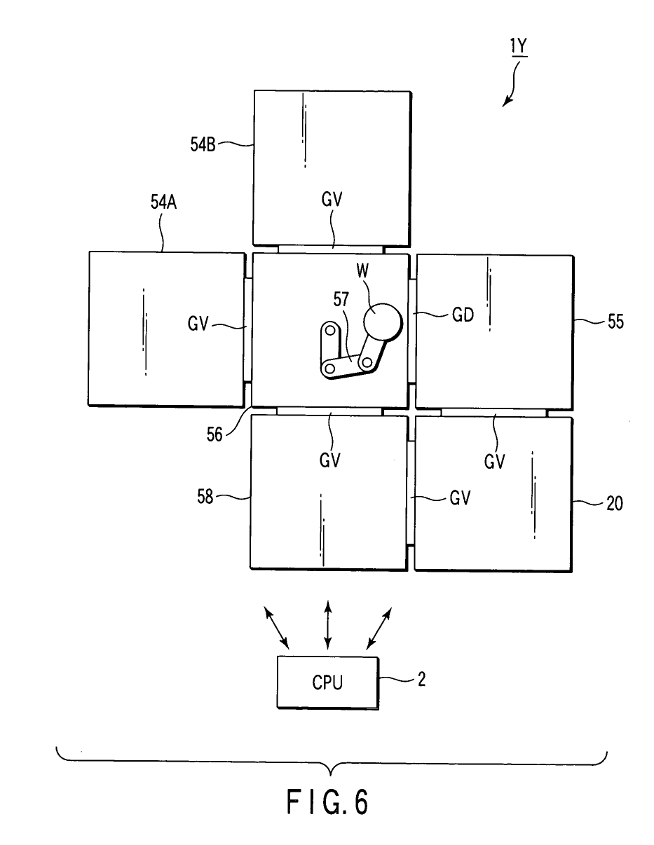

FIG. 6 is a plan view showing the layout of a semiconductor processing system according to a third embodiment of the present invention. This semiconductor processing system 1Y also has a multi-chamber type structure including a plurality of single-object type process chambers. Each process chamber is arranged to accommodate a single semiconductor wafer W as a target object, which is processed under the vacuum environment. The operation of the semiconductor processing system 1Y is controlled by a CPU 2.

To be more specific, the processing system 1Y according to the third embodiment comprises a rectangular common transfer chamber 56. Two process chambers 54A and 54B, a single storage chamber 55, and a single load lock chamber 58 are connected to the common transfer chamber 56. The chambers 54A, 54B, and 58 are connected to the sidewalls of the transfer chamber 56 with gate valves GV interposed therebetween, and the storage chamber 55 is connected to the remaining sidewall of the transfer chamber 56 with a gate door GD (which is lower in its pressure resistance than the gate valve) interposed therebetween.

The process chambers 54A and 54B, the transfer chamber 56, the transfer mechanism 57, and the load lock chamber 58, which are included in the semiconductor processing system 1Y according to the third embodiment, are substantially equal to those included in the semiconductor processing system according to the second embodiment described above. As described previously, the load lock chamber 58 is capable of controlling the inner pressure thereof by gas supply and vacuum-exhaust into and from the load lock chamber 58 to control the inner pressure within a range of between atmospheric pressure and a vacuum. The load lock chamber 58 is used for maintaining the vacuum state within the transfer chamber 56 when the semiconductor wafer W is transferred toward and from the process chambers 54A and 54B.

On the other hand, the storage chamber 55 is used for temporarily storing the semiconductor wafer W in the case where the process chambers 54A and 54B are under operation. Further, the CPU 2 of the semiconductor processing system 1Y monitors the operating state of the process chambers 54A and 54B and causes the transfer mechanism 57 to transfer the wafer W from the storage chamber 55 into the process chambers 54A and 54B based on the monitored operating state of the process chambers 54A and 54B.

A minus ion generator 20 is disposed in a space between the storage chamber 55 and the load lock chamber 58. The minus ion generator 20 is connected to the sidewalls of the storage chamber 55 and the load lock chamber 58 with gate valves GV interposed therebetween. Further, the minus ion generator 20 is connected as required to the process chambers 54A and 54B via the ion transfer tubes described previously. The minus ion generator 20 is arranged as described previously with reference to FIG. 2.

<Load Lock Chamber and Storage Chamber>

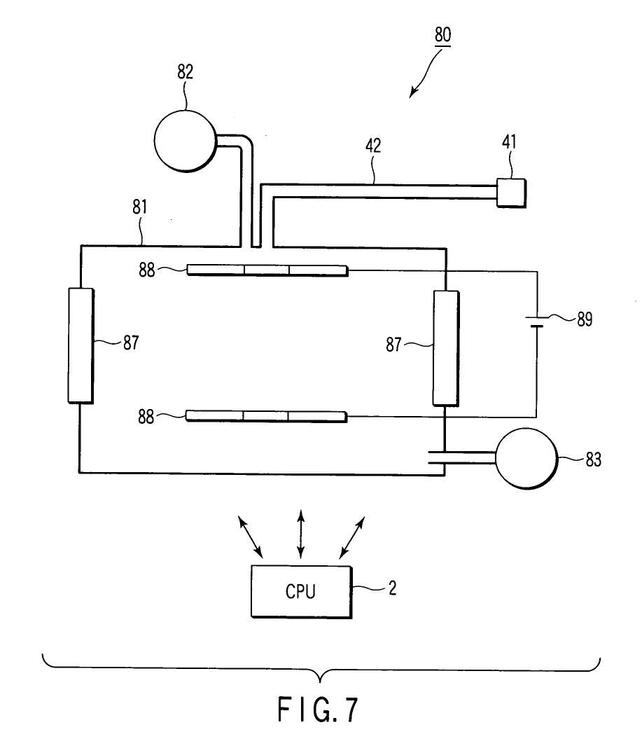

FIG. 7 shows the structure of a chamber apparatus 80 that can be used for forming one of the load lock chamber 58 and the storage chamber 55. The chamber apparatus 80 includes a hermetic chamber 81 capable of controlling the inner pressure by gas supply and vacuum-exhaust into and from the chamber 81 to control the inner pressure of the chamber 81 within a range of between atmospheric pressure and a vacuum. A gas supply unit 82 and an exhaust unit 83 are connected to the chamber 81 for supplying and exhausting gas into and from the chamber 81. Incidentally, where the chamber apparatus 80 is applied to the storage chamber 55, the gas supply unit 82 and the exhaust unit 83 can be those used for the transfer chamber 56 as well.

The ion distributing portion 41 included in the minus ion generator 20 is connected to the chamber 81 via the ion transfer tube 42. The minus ions supplied into the chamber 81 are used for negatively charging particles present within the chamber 81. Where an electric field is formed within the chamber 81 as described later while the particles are negatively charged, the electric field causes the charged particles to be collected on the electrode-function portion on the positive side.

A pair of upper and lower electrodes 88 are disposed within the chamber 81. A voltage is selectively supplied from a DC power supply 89 to the electrodes 88 to form an electric field within the chamber 81. As described above, the electric field causes the particles negatively charged by the minus ions to be collected on one of the electrodes 88, i.e., the positive electrode 88. Also, UV irradiation sources 87 are disposed on both sidewalls of the chamber 81. The UV irradiating sources 87 irradiate the interior of the chamber 81 with an ultraviolet rays having a wavelength not longer than 200 nm.

### Operation of Minus Ion Generator in Third Embodiment

The operation of the minus ion generator 20 included in the semiconductor processing system 1Y according to the third embodiment will now be described. Where the chamber apparatus 80 is applied to the load lock chamber 58, the chamber apparatus 80 is arranged to accommodate a wafer cassette, for example. In this case, the wafer cassette is transferred into the chamber 81 through the open portion (not shown) formed in the front wall of the chamber 81 (or load lock chamber 58).

After the transfer of the wafer cassette into the chamber 81, the CPU 2 for controlling the operation of the semiconductor processing system 1Y acts to exhaust gas from the chamber 81 to lower the inner pressure of the chamber 81 and, at the same time, to remove the particles within the chamber 81. Then, the gate valve GV between the chamber 81 and the transfer chamber 56 (see FIG. 6) is opened to allow the transfer mechanism 57 to take out semiconductor wafers W from the wafer cassette. Then, one of the wafers W is transferred by the transfer mechanism 57 from the transfer chamber 56 into each of the process chambers 54A and 54B for applying a predetermined process to the wafer W. After the wafer W is subjected to the predetermined process, it is transferred back into the chamber 81 via the opposite route to have the wafer W stored in the wafer cassette. Then, the inner pressure of the chamber 81 is brought back to atmospheric pressure in order to take the wafer cassette from the chamber 81.

In the process described above, particles may be left in the chamber 81 (or load lock chamber 58) accommodating the wafer cassette, in spite of particle removal by vacuum-exhaust. Therefore, after the interior of the chamber 81 is exhausted to set up a vacuum state within the chamber 81, minus ions are supplied from the minus ion generator 20 into the chamber 81 to charge negatively the remaining particles. At the same time, a voltage is applied between the pair of the electrodes 88 to form an electric field within the chamber 81. As a result, the electric field causes the charged particles to be collected on the positive electrode (one of the electrodes 88), thereby preventing the remaining particles from being attached to the wafer W.

It is desirable for the electric field to be maintained during at least the period between the time when the wafer cassette is opened for taking out wafers W and the time when the wafer cassette storing the wafers W processed is closed. In other words, it is desirable for the electric field to be maintained during the period between the time when the inner S pressure of the chamber 81 is lowered from atmospheric pressure to a vacuum and the time when the inner pressure of the chamber 81 is increased from a vacuum to atmospheric pressure. Alternatively, the electric field may be always maintained during the use of the semiconductor processing system 1Y.

In place of the electrodes 88, a conductive portion (e.g., the sidewall of the chamber 81) disposed inside or outside the chamber 81 may be used to form an electric field within the chamber 81. Therefore, in the present specification, the mechanism for forming an electric field within the chamber is also called an electric field-forming mechanism and the member imparted with the positive or negative potential for forming the electric field is also called an electrode-function portion. In this case, it is desirable for the electrode-function portion on the positive side for collecting the charged particles to be exposed within the chamber 81. It is also desirable for the electrode-function portion to be easily detachable in view of the maintenance of the apparatus. In the case of, for example, the electrodes 88, the particles accumulated on the electrodes 88 can be removed by washing the electrodes 88 at the maintenance time.

When a voltage is applied to the pair of the electrodes 88 disposed within the chamber 81, particles are collected by one of the electrodes 88. Since oxygen minus ions are capable of reacting a contexture inside, it is possible to remove particles present inside the contexture.

Where the chamber 80 is applied to the storage chamber 55, the operation of the minus ion generator 20 is performed based on the similar view point. Specifically, minus ions are supplied from the minus ion generator 20 into the chamber 81 (or storage chamber 55) to charge negatively particles present within the chamber 81. At the same time, a voltage is applied between the pair of the electrodes 88 to form an electric field within the chamber 81, with the result that the charged particles are collected on the positive electrode (one of the pair of the electrodes 88). It follows that the residual particles are prevented from being attached to the wafer W.

### Matters Common to First to Third Embodiments

The first to third embodiments are described above separately, but their features may be appropriately combined. For example, the method of preventing the residual particles from being attached to a wafer W within a process chamber described in each of the first and second embodiment may be simply combined with the method of preventing the residual particles from being attached to a wafer W within a load lock chamber employed in the third embodiment.

Each of the embodiments described above is directed to the technique of negatively charging the particles to prevent the particles from being attached to the semiconductor wafer. However, in each of the embodiments described above, it is possible to supply minus ions to wash the surface of a semiconductor wafer W. Specifically, since oxygen minus ions are capable of reacting a contexture inside, it is possible to simultaneously remove organic materials present on the surface of a film formed on the wafer W.

In the case of plasma cleaning processes applied within a chamber, they have to be performed separately from removal of organic materials from the surface of a semiconductor film on a semiconductor wafer, because they can etch the film itself. However, according to the embodiments described above, since minus ions are utilized, it is possible to simultaneously perform chamber cleaning and removal of organic materials from a wafer.

The technical idea of the present invention can also be applied similarly to an in-line type semiconductor processing system as well as to the multi-chamber type semiconductor processing system. Also, the target object to be processed is not limited to a semiconductor wafer, and it may be a substrate for a liquid crystal display device. Particularly, an improvement in the yield of the processing can be expected in the case of employing the technical idea of the present invention for the processing of a substrate essentially containing a large amount of impurities, such as a soda glass.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vacuum processing system, comprising:
a process chamber configured to accommodate a target object and perform a process thereon under a vacuum environment;
an exhaust system configured to exhaust an interior of the process chamber;
a gas supply system configured to supply a process gas into the process chamber;
an ion generator configured to generate minus ions and disposed in a space outside the process chamber, the space being arranged to selectively communicate with the interior of the process chamber; and
a negative charge applicator configured to form a negatively charged state of the target object within the process chamber.

2. The system according to claim 1, further comprising a control section configured to control an operation of the vacuum processing system, wherein the control section is arranged to form a negatively charged state of the target object by the negative charge applicator and to supply minus ions from the ion generator into the process chamber so as to charge negatively particles present therein, thereby preventing the particles from being attached to the target object.

3. The system according to claim 1, wherein the system comprises a plurality of process chambers, to which the ion generator is connected through an ion distributing portion.

4. The system according to claim 1, wherein the ion generator comprises a heater configured to heat a source material containing minus ions, and a member configured to apply an electric field to the source material thereby extracting minus ions from the source material.

5. The system according to claim 1, wherein the negative charge applicator comprises a power supply configured to apply a negative bias to the target object.

6. The system according to claim 1, wherein the process chamber comprises a film-formation process chamber, and the ion generator is directly connected to the process chamber through a gate valve.

7. The system according to claim 2, wherein the control section is arranged to supply minus ions into the process chamber after finishing the process within the process chamber and before transferring the target object out of the process chamber.

8. The system according to claim 1, further comprising:
a transfer chamber connected to the process chamber to transfer the target object into and out of the process chamber;
a load lock chamber capable of controlling inner pressure thereof between atmospheric pressure and a vacuum and connected to the transfer chamber, the load lock chamber being configured to be supplied with minus ions from the ion generator or another ion generator; and
an electric field-forming mechanism configured to form an electric field within the load lock chamber.

9. The system according to claim 8, further comprising a control section configured to control an operation of the vacuum processing system, wherein the control section is arranged to form an electric field within the load lock chamber by the electric field-forming mechanism and to supply minus ions from the ion generator into the load lock chamber so as to charge negatively particles present therein, thereby collecting the particles by the electric field.

10. The system according to claim 9, wherein the control section is arranged to form a negatively charged state of the target object by the negative charge applicator and to supply minus ions from the ion generator into the process chamber so as to charge negatively particles present therein, thereby preventing the particles from being attached to the target object,
the control section is arranged to supply minus ions into the process chamber after finishing the process within the process chamber and before transferring the target object out of the process chamber, and
the control section is arranged to supply minus ions into the load lock chamber and form an electric field within the load lock chamber after adjusting pressure within the load lock chamber from atmospheric pressure to a vacuum, and, then, to continue to form the electric field within the load lock chamber until adjusting the pressure within the load lock chamber from a vacuum to atmospheric pressure.

11. A vacuum processing system, comprising:
a process chamber configured to accommodate a target object and perform a process thereon under a vacuum environment;
an exhaust system configured to exhaust an interior of the process chamber;
a gas supply system configured to supply a process gas into the process chamber;
a transfer chamber connected to the process chamber to transfer the target object into and out of the process chamber;
a load lock chamber capable of controlling inner pressure thereof between atmospheric pressure and a vacuum and connected to the transfer chamber;
an ion generator configured to generate minus ions that are supplied into the load lock chamber; and
an electric field-forming mechanism configured to form an electric field within the load lock chamber.

12. The system according to claim 11, further comprising a control section configured to control an operation of the vacuum processing system, wherein the control section is arranged to form an electric field within the load lock chamber by the electric field-forming mechanism and to supply minus ions from the ion generator into the load lock chamber so as to charge negatively particles present therein, thereby collecting the particles by the electric field.

13. The system according to claim 11, wherein the electric field-forming mechanism comprises an electrode-function portion disposed within the load lock chamber and configured to be supplied with a positive potential, such that the particles are collected on the electrode-function portion.

14. The system according to claim 11, further comprising:
a storage chamber connected to the transfer chamber to temporarily store the target object, and configured to be supplied with minus ions from the ion generator or another ion generator; and
an electric field-forming mechanism for storage configured to form an electric field within the storage chamber.

15. The system according to claim 14, further comprising a control section configured to control an operation of the vacuum processing system, wherein the control section is arranged to form an electric field within the storage chamber by the electric field-forming mechanism for storage and to supply minus ions into the storage chamber so as to charge negatively particles present therein, thereby collecting the particles by the electric field.

16. The system according to claim 11, wherein the ion generator comprises a heater configured to heat a source material containing minus ions, and a member configured to apply an electric field to the source material thereby extracting minus ions from the source material.

17. The system according to claim 12, wherein the control section is arranged to supply minus ions into the load lock chamber and form an electric field within the load lock chamber after adjusting pressure within the load lock chamber from atmospheric pressure to a vacuum, and, then, to continue to form the electric field within the load lock chamber until adjusting the pressure within the load lock chamber from a vacuum to atmospheric pressure.

18. A method of using a vacuum processing system, comprising:
subjecting a target object to a process under a vacuum environment within a process chamber;
forming a negatively charged state of the target object within the process chamber; and
supplying minus ions into the process chamber to charge negatively particles present therein, thereby preventing the particles from being attached to the target object.

19. The method according to claim 18, further comprising:
forming an electric field within a load lock chamber connected to the process chamber through a transfer chamber;
supplying minus ions into the load lock chamber to charge negatively particles present therein, thereby collecting the particles by the electric field.

20. A method of using a vacuum processing system, comprising:
forming an electric field within a hermetic chamber connected to a process chamber configured to accommodate a target object and perform a process thereon under a vacuum environment; and
supplying minus ions into the hermetic chamber to charge negatively particles present therein, thereby collecting the particles by the electric field.
